(19) United States
(12) Patent Application Publication
(10) Pub. No.: US 2020/0120753 A1
(43) Pub. Date: Apr. 16, 2020

(54) Modular Circuit Board for Telecommunications System

(71) Applicant: Hook'd WiFi Inc., Lubbock, TX (US)

(72) Inventors: Frank Carlo Pallone, Plano, TX (US); Jacob Alexander Kirkland, Plano, TX (US)

(21) Appl. No.: 16/161,304

(22) Filed: Oct. 16, 2018

Related U.S. Application Data
(63) Continuation of application No. 16/161,223, filed on Oct. 16, 2018.

(51) Int. Cl. H04W 88/08; H01Q 21/20; H04W 72/04; H04B 7/04; H05K 1/02

(52) U.S. Cl. CPC H04W 88/08; H01Q 21/205; H05K 1/0243; H04B 7/04; H04W 72/0486

(57) ABSTRACT

A modular circuit board for use in a telecommunications network may comprise a plurality of modules, each module operable as an independent circuit board and capable of communicating with a device and a central controller for processing information and distributing workload across the plurality of modules. Each module of the plurality of modules may be interchangeable, removeable, and/or customizable.

### CROSS REFERENCE TO RELATED APPLICATIONS

This application is a continuation of U.S. application Ser. No. 16/161,223, filed on Oct. 16, 2018 and entitled “Wireless Access Point Using Stacked Antennas”, which is hereby incorporated by reference for all purposes.

### FIELD OF THE INVENTION

The present disclosure relates to systems and methods for improving a wireless access point in a telecommunications network. More particularly, the present disclosure relates to a configurable wireless access point comprising a stacked antenna array.

The present disclosure further relates to a modular circuit board for use in a telecommunications network, and particularly for use with a wireless access point.

### BACKGROUND

Wireless networking is becoming increasingly common, offering users the ability to move around from one site to another within a coverage area without having to operate from a wired port in a fixed location. A wireless access point (WAP), also known simply as “access point” (AP), is a networking hardware device on a wireless local area network (WLAN) that allows wireless-capable devices to connect to a wired network through a wireless standard, such as Wi-Fi.

Wi-Fi is a wireless communication scheme conforming to the 802.11 standards of The Institute of Electrical and Electronics Engineers, Inc. (IEEE). In the Wi-Fi scheme, two frequency bands are presently authorized by the Federal Communications Commission for wireless communication, namely the 2.4 GHz and 5.0 GHz wireless radio bands. Each of these wireless radio bands offers different capability. For example, the longer waves used by the 2.4 GHz band are better suited to longer ranges and improved transmission through walls, buildings, and other objects; however, the 2.4 GHz band is more congested and slower in speed. The shorter waves used by the 5 GHz band results in reduced range and diminished ability to penetrate walls and objects, but the 5 GHz band is less congested and transmits at higher speeds.

The 802.11 standard also provides for several distinct radio frequencies within each frequency band. Each distinct radio frequency—or channel—within a frequency band overlaps with adjacent channels on the same frequency band. Traditionally, a WAP is configured with one or more omnidirectional antennas, and the antennas transceive on a channel within a frequency band. Devices on a channel must share the available bandwidth with all other devices on a channel. Allocation of finite bandwidth on a channel among numerous devices operating in the same geographic area is typically achieved with a multiplexing scheme such as orthogonal frequency-division multiplexing (“OFDM”).

Wireless access points and other such devices in a telecommunications network are further configured to electrically communicate with electronic circuit boards. In a conventional wireless access point, for example, the omnidirectional antennas of the wireless access point may be configured to electrically communicate with a single electronic circuit board. As a result, an update to any one of the antennas may necessitate replacement of the entire electronic circuit board. Similarly, the subsequent addition of one or more antennas to the conventional wireless access point may require the addition of one or more entirely-new electronic circuit boards.

### SUMMARY

The present disclosure relates to a modular circuit board for use in a telecommunications network.

In some implementations, the modular circuit board for use in a telecommunications network may comprise a plurality of modules, each module operable as an independent circuit board and capable of communicating with a device; and a central controller for processing information and distributing workload across the plurality of modules. Each module of the plurality of modules may be interchangeable, removeable, and/or customizable.

The details of one or more implementations are set forth in the accompanying drawings and the description below. Other features, objects, and advantages of the implementations will be apparent from the description and drawings.

### BRIEF DESCRIPTION OF THE DRAWINGS

For a more complete understanding of this disclosure and its features, reference is now made to the following description, taken in conjunction with the accompanying drawings, in which:

FIG. 1 illustrates a plan view of a wireless access point having a stacked antenna configuration, according to the present disclosure;

FIG. 2 illustrates a perspective view of the wireless access point having a stacked antenna configuration of FIG. 1, according to the present disclosure;

FIG. 3A illustrates a plan view of a single sectored antenna that may be used in a stacked antenna array, according to the present disclosure;

FIG. 3B illustrates a perspective view of the single sectored antenna of FIG. 3A, according to the present disclosure;

FIG. 4 illustrates a block diagram of a modular circuit board that may be used in a wireless access point having a stacked antenna array, according to the present disclosure;

FIG. 5 illustrates a block diagram of representative modules of the modular circuit board of FIG. 4, according to the present disclosure;

FIG. 6 illustrates a block diagram of an implementation of a radio module of the representative modules of the modular circuit board of FIG. 5, according to the present disclosure;

FIG. 7 illustrates an exploded plan view of a housing for enclosing a stacked antenna array, according to the present disclosure;

FIG. 8 illustrates a perspective view of an assembled housing for enclosing a stacked antenna array, according to the present disclosure;

FIG. 9A illustrates a plan view of a cable mount, according to the present disclosure;

FIG. 9B illustrates a perspective view of the cable mount of FIG. 9A, according to the present disclosure; and

FIG. 10 illustrates an assembled housing coupled to a support column, according to the present disclosure.

Like reference symbols in the various drawings indicate like elements.

### DETAILED DESCRIPTION

Conventional wireless access points typically utilize one or more omnidirectional antennas which offer a 360-degree radiation pattern and operate at a singular radio band. The disadvantages of such systems include limitations on range of coverage, lack of system flexibility, and difficulties in managing system upgrades. Additionally, under conventional systems, migration to new wireless technologies may require a complete replacement of existing wireless access points.

Because Wi-Fi devices operate within a finite spectrum of available bandwidth, the overall performance of a wireless network will decrease as the number of devices and wireless access points within a geographic area increases. As consumers increasingly rely on mobile communications devices, the number of wireless access points in cities and other populated geographic areas will continue to increase. Accordingly, channel congestion will increase, thereby decreasing communications performance for all devices in an area. However, wireless communications performance may be improved when transceivers within a geographic area operate on non-overlapping channels. Performance may be further improved when transceivers operate on different channels from other transceivers within the same geographic area. As consumers increase mobility and demand greater flexibility, the configurable wireless access point described in the present disclosure offers varied options for Wi-Fi connectivity and allows for continued improvement in wireless technology.

Moreover, the one or more omnidirectional antennas utilized by a conventional wireless access point is typically configured to electrically communicate with a single electronic circuit board. Thus, an update to or replacement of one or more antennas may require replacement of the entire electronic circuit board. Likewise, the later addition of one or more antennas to the wireless access point may require the addition of new, corresponding electronic circuit boards. These configurations not only impose physical burdens on the system (i.e., physical space, additional bus structures, wiring, etc.), but also reduce the ease and flexibility desired in a field that is constantly advancing. The modular circuit board described in the present disclosure allows for the configuration of a plurality of independent circuit modules, each of which is independently configurable and interchangeable, thereby minimizing impact to the system as a whole.

Embodiments of the present disclosure are directed to a configurable wireless access point having a stacked antenna array and a modular circuit board for use with the configurable wireless access point. In an implementation, the stacked antenna array may comprise one or more stacked layers of antennas, each layer of antennas directed to a different wireless radio band, and each antenna within each layer of antennas being sectored and directional. As described in detail below, such arrangement increases range of wireless coverage, improves system flexibility, and allows for ease in system maintenance and upgrade.

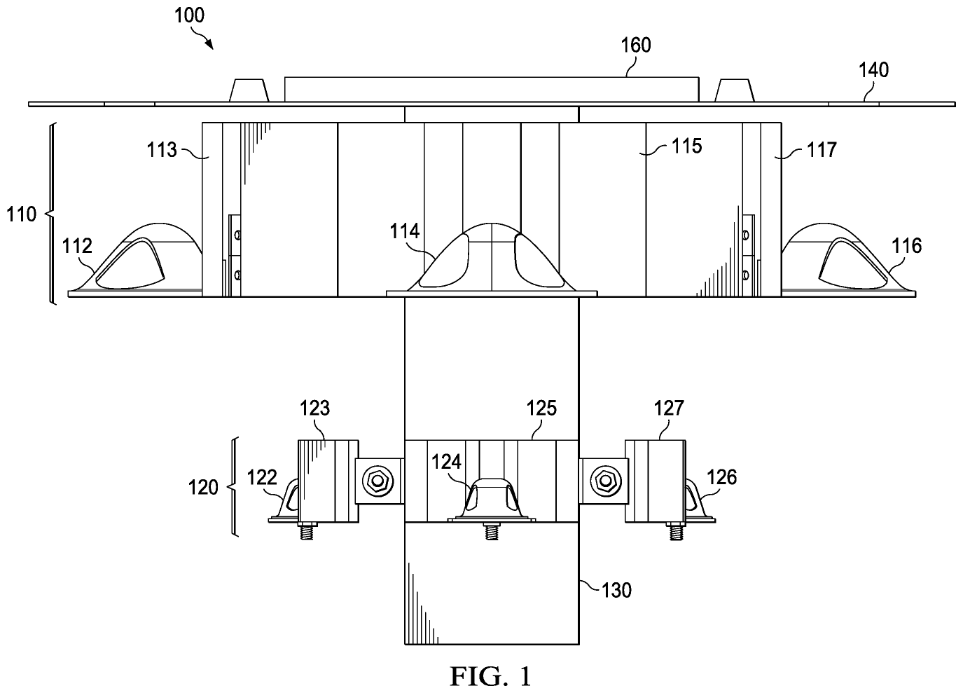

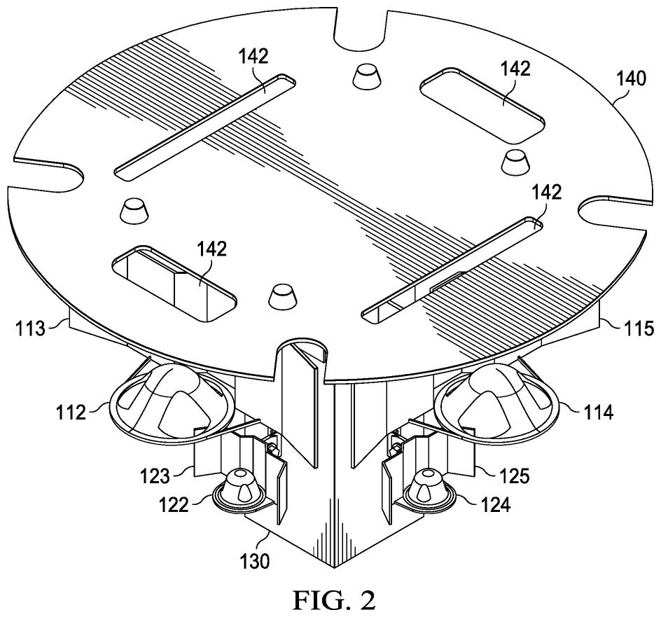

Reference is made to FIGS. 1 and 2, which depict in plan view and perspective view, respectively, a wireless access point 100 having a stacked antenna configuration according to the present disclosure. Wireless access point 100 may comprise a first antenna layer 110 having one or more antenna 112, 114, 116 operating at a first wireless radio band. The first wireless radio band may comprise, e.g., a 2.4 GHz wireless radio band, a 5 GHz wireless radio band, or other wireless frequency known, used, developed, or to be standardized in the art. The one or more antenna 112, 114, 116 of the first antenna layer 110 may be supported by support structure 130. In an implementation, support structure 130 may comprise a metal support, such as a square pole, round pole, or other similar structure to which the one or more antenna 112, 114, 116 may be affixed.

With continued reference to FIGS. 1 and 2, wireless access point 100 may further comprise a second antenna layer 120 having one or more antenna 122, 124, 126 operating at a second wireless radio band. The second wireless radio band may comprise a wireless frequency different from the first wireless radio band. For example, if the first wireless radio band is designated to a 2.4 GHz wireless frequency, then the second wireless radio band may be designated to a 5 GHz wireless frequency or any other wireless frequency known, used, developed, or to be standardized in the art. The one or more antenna 122, 124, 126 of the second antenna layer 120 may also be supported by support structure 130.

Importantly, the first antenna layer 110 operating at a first wireless radio band and the second antenna layer 120 operating at a second wireless radio band may be arranged in a stacked configuration, i.e., with a first antenna layer 110 stacked atop a second antenna layer 120 and supported by support structure 130, as depicted in FIGS. 1 and 2. One benefit of this configuration is the ease with which the wireless access point 100 may be modified, customized, or upgraded without removing and/or rebuilding the entire configuration. For example, as technology continues to improve, potential changes in the Wi-Fi standard (e.g., to a standard other than the 2.4 GHz or 5.0 GHz wireless frequencies) would not necessitate the removal or rebuilding of the entire wireless access point. Instead, outdated antennas and/or antenna layers may be replaced as needed.

While FIGS. 1 and 2 depict three antennas 112, 114, 116 at the first antenna layer 110 and three antennas 122, 124, 126 at the second antenna layer 120, the present disclosure is not limited to any particular number of antennas or any particular number of antenna layers. As described in detail below, additional antennas may be incorporated at each antenna layer to increase the capacity and directional distance of the wireless access point 100.

With continued reference to FIGS. 1 and 2, in an implementation, the first antenna layer 110 may be sectored to divide up the first antenna layer 110 circumferentially (at least 360°) around the wireless access point 100, i.e., with each of the one or more antenna 112, 114, 116 assigned to a different sector 113, 115, 117. Likewise, the second antenna layer 120 may also be sectored, with each of the one or more antenna 122, 124, 126 assigned to a different sector 123, 125, 127. Sectorization of antennas at an antenna layer widens the coverage area of the network and therefore increases the number of clients that may be served by the wireless access point 100.

In an implementation, if the first antenna layer 110 is sectored, the one or more antenna 112, 114, 116 in the first antenna layer 110 may comprise one or more directional antenna, each directional antenna assigned to a different sector in the first antenna layer 110. Similarly, if the second antenna layer 120 is sectored, the one or more antenna 122, 124, 126 in the second antenna layer 120 may comprise one or more directional antenna, each directional antenna assigned to a different sector in the second antenna layer 120. Each of the one or more directional, sectored antenna in the first and/or second antenna layer may operate at a designated channel, with adjacent sectors in a given antenna layer operating at different designated channels to reduce signal interference. Channels may be designated and assigned based on interference patterns. For example, channels 1, 6, and 11 may be non-overlapping channels deemed as having minimal interference. Thus, adjacent sectors in a given antenna layer may operate at a different one of channels 1, 6, or 11. By employing sectored, directional antennas, the wireless access point 100 not only increases its capacity, but also increases its directional distance/range.

The one or more sectored, directional antenna may operate in any number of configurations, including, e.g., 120°, 60°, or 30° configurations. In an implementation, a 120° configuration may comprise four sectored, directional antennas arranged circumferentially (to cover at least 360° around the wireless access point 100) and equidistantly around the support structure 130 in the first and/or second antenna layers. This configuration ensures overlap in coverage between adjacent sectors, thereby avoiding gaps in the network. As a result, the Wi-Fi signal of a device of a user traveling between ranges of adjacent sectors may be handed off to the next antenna and thereby minimize signal drop-off.

In another implementation, a 60° configuration may comprise eight sectored, directional antennas arranged around the support structure in the first and/or second antenna layers. In yet another implementation, a 30° configuration may comprise sixteen sectored, directional antennas arranged around the support structure in the first and/or second antenna layers. Although 120°, 60°, and 30° configurations are described, the present disclosure is not limited to any particular configuration or to the use of any particular number of sectored, directional antennas. Moreover, various configurations may be applied to various antenna layers.

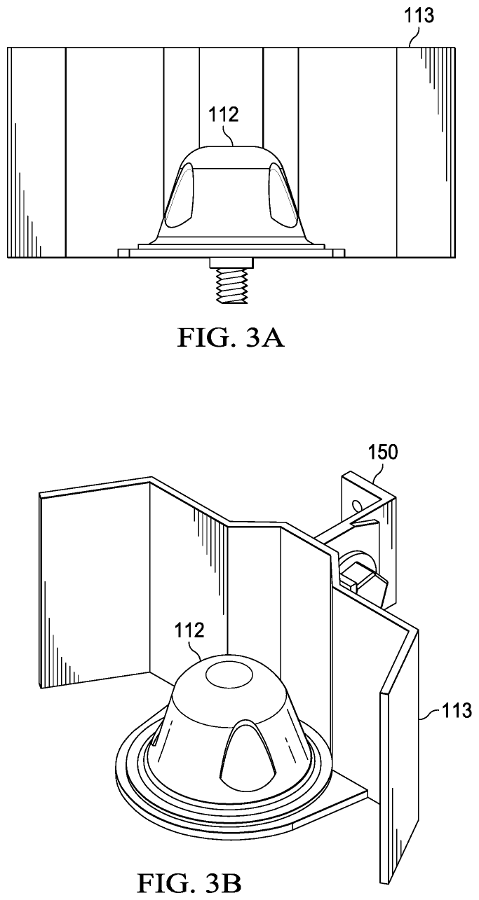

Reference is now made to FIGS. 3A and 3B, which depict detailed plan and perspective views, respectively, of a sectored antenna according to the present disclosure. While the antenna shown in FIGS. 3A and 3B is designated antenna 112, it may be any one of the antenna 112, 114, 116, 122, 124, 126 shown in FIGS. 1 and 2. Likewise while the sector shown in FIGS. 3A and 3B is designated sector 113 (corresponding to associated antenna 112), it may be any one of the sectors 113, 115, 117, 123, 125, 127 shown in FIGS. 1 and 2. Importantly, only one antenna may be assigned to each sector. Sector 113 may physically be coupled to support structure 130 via sector mount 150. Sector mount 150 may be removably attached to support structure 130 via screws, bolts, or any other connection means known in the art.

With further reference to the wireless access point 100 of FIGS. 1 and 2, a ground plate 140 may be layered atop the first antenna layer 110 and coupled to support structure 130. Ground plate 140 may serve as a grounding structure and may allow for the placement of one or more electronic circuit boards 160 thereupon. As shown in FIG. 2, ground plate 140 may be configured with slots 142 through which connection wires/cables from one or more electronic circuit boards 160 may be guided for connection to the one or more antennas 112, 114, 116, 122, 124, 126 of the wireless access point 100. Each of the one or more electronic circuit boards 160 may be configured to electrically communicate with the one or more antennas 112, 114, 116, 122, 124, 126 of the first and/or second antenna layers 110, 120, and may include, e.g., a processor, a memory, storage, and other electronic components known in the art.

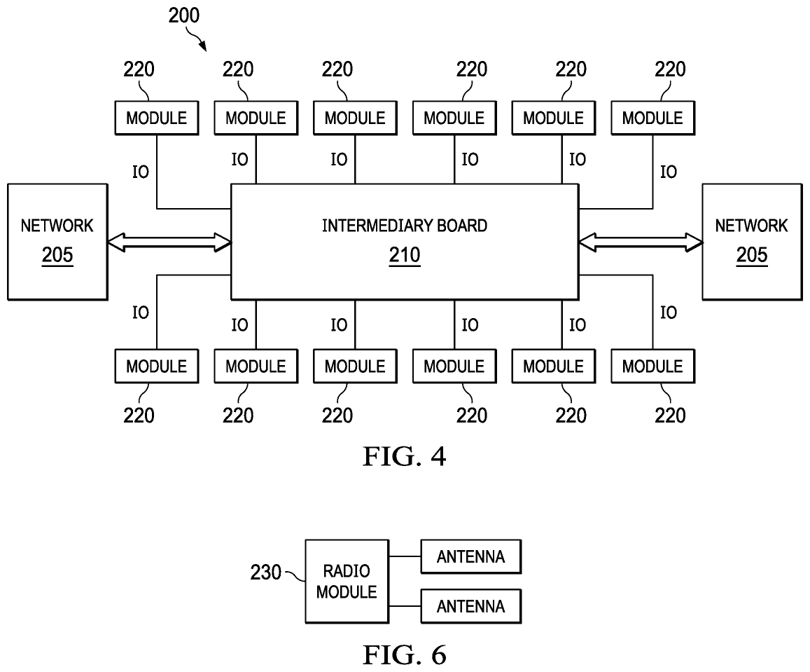

With reference now to FIG. 4, according to an implementation, the electronic circuit board for use with the wireless access point 100 may comprise a modular circuit board 200. Modular circuit board 200 may be mounted on ground plate 140 and may comprise a plurality of modules 220 (collectively numbered 220 in FIG. 4), each module operable as an independent and separate circuit board. In an implementation, each of the one or more modules of the plurality of modules 220 may be assigned to electrically communicate with a separate one of the one or more antennas 112, 114,116, 122, 124, 126 of the first and second antenna layers 110, 120. In yet another implementation, certain modules of the plurality of modules 220 may be directed to other functionalities that advance the operation of the wireless access point 100. The modular circuit board 200 may further comprise an intermediary board (or central controller) 210 operable to facilitate communication between the plurality of modules 220 and with a network 205. Modular circuit board 200 may also comprise one or more connection points for connection to ethernet, fiber, power, and other such cable connections.

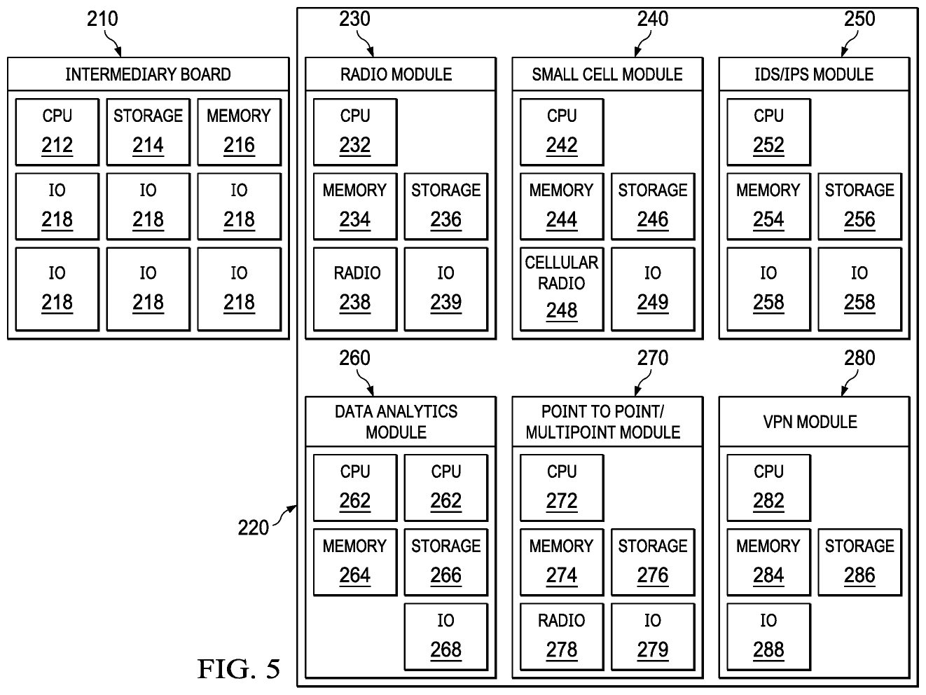

Reference is now made to FIG. 5, which depicts block diagrams of the components comprising the intermediary board 210 and exemplary modules of the plurality of modules 220 of the modular circuit board 200 of FIG. 4. The plurality of modules 220 may comprise, for example, one or more radio module 230, small cell module 240, security module 250, data analytics module 260, point-to-point/multipoint module 270, and VPN module 280.

Intermediary board (or central controller) 210 may facilitate the processing of information and distribution of work load across the plurality of modules 220, and may comprise a central processing unit 212 for processing information obtained from the plurality of modules 220, storage 214 for storing long-term data, memory 216 for storing short-term data, and a plurality of input/output nodes 218 for connection to the plurality of modules 220.

Next, the plurality of modules 220 may comprise, for example, one or more radio modules 230, as shown in FIGS. 5 and 6. The one or more radio modules 230 may be configured to provide Wi-Fi radio connectivity for the wireless access point 100. In an implementation, each radio module of the one or more radio modules 230 may be electrically coupled to a separate one of the one or more antenna 112, 114, 116 of the first antenna layer 110 and/or a separate one of the one or more antenna 122, 124, 126 of the second antenna layer 120 of the wireless access point 100. In another implementation, and as shown in FIG. 6, a single radio module 230 may be electrically coupled to two or more antennas in one or more antenna layers. Based on a given number of users and the capacity of the wireless access point, any configuration of radio module 230 to antenna(s) may be accommodated according to the present disclosure. Radio module 230 may offer Wi-Fi 1-6 (formerly, A/B/G/N/AC/AX) coverage and may support a combination of wireless radio bands, including 2.4 GHz and 5 GHz bands, WPA/WPA2/WPA3 encryption, and mesh capabilities. Radio module 230 may comprise, for example, a central processing unit 232, memory 234, storage 236, radio 238, and input/output node 239.

As shown in FIG. 5, the plurality of modules 220 may further comprise small cell module 240. Small cell module 240 may provide cellular wide area network (WAN) connectivity to the wireless access point 100 and support cellular carrier offloading. The small cell module 240 may provide 3G, 4G, and 5G connectivity to the access point, without the need for additional infrastructure. Small cell module 240 may comprise, for example, a central processing unit 242, memory 244, storage 246, cellular radio 248, and input/output node 249.

Security module 250 may add comprehensive security features such as intrusion detection systems (IDS) and intrusion protection systems (IPS). IDS and IPS may parse and interpret network data and host activities. Such data may range from network packet analysis to the contents of log files from routers, firewalls, servers, local system logs, access calls, and network flow data. Security module 250 may comprise, for example, a central processing unit 252, memory 254, storage 256, and input/output nodes 258. Two input/output nodes 258 may be used, operating as a passthrough so that one input/output node allows data traffic in and one input/output node allows data traffic out. This may allow for a more comprehensive analysis of data traffic and identification of vulnerabilities in the system. In other implementations, a single input/output node may also be employed.

Data analytics module 260 may collect data gathered by the wireless access point 100 and send the data to the management platform. The management platform (not shown) may be a server that is utilized for aggregation, processing, and detailed analysis of data gathered by the wireless access point 100. The management platform may reside on a cloud may comprise a physical server stored in a data center. The data analytics module 260 may be used to improve network performance and offer users improved connectivity. Data analytics module 260 may comprise, for example, central processing units 262, memory 264, storage 266, and input/output node 268. At least two central processing units 262 are preferred, allowing for faster processing of gathered data.

Point-to-Point/Multipoint module 270 may offer point-to-point, point-to-multipoint, and multipoint-to-multipoint connectivity for long distances outside the range of mesh capabilities. The operating frequencies may encompass the 900 MHz, 2.4 GHz, 3.65 GHz, and 5 GHz ranges or additional radio frequencies as they are approved for utilization. Point-to-Point/Multipoint module 270 may comprise, for example, a central processing unit 272, memory 274, storage 276, radio 278, and input/output node 279.

VPN Module 280 may provide secure, encrypted connectivity on a per-client basis and may allow the wireless access point 100 to support a large volume of encrypted connections. This type of connectivity may be preferred in environments with specific compliance requirements. VPN Module 280 may comprise, for example, a central processing unit 282, memory 284, storage 286, and input/output node 288.

Although the modular circuit board 200 is described above in conjunction with specific modules (each having specific functionality), it is to be understood that the modular circuit board of the present disclosure may comprise any number of modules having any functionality desired and/or relevant in the art. The number and types of modules on the modular circuit board may be limited only by physical constraints such as limitations on power and bus structures. Additionally, while modular circuit board 200 and modules 220-280 are described above in conjunction with wireless access point 100, it is to be understood that the modular circuit board of the present disclosure may be configured to operate in various applications, for various purposes, and in various systems, particularly in cellular applications and other such telecommunications systems.

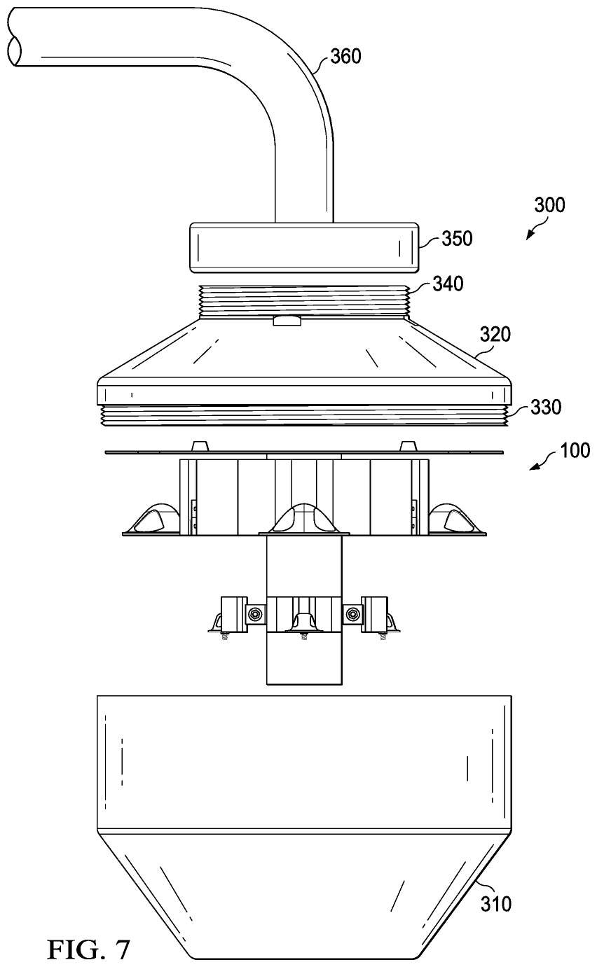

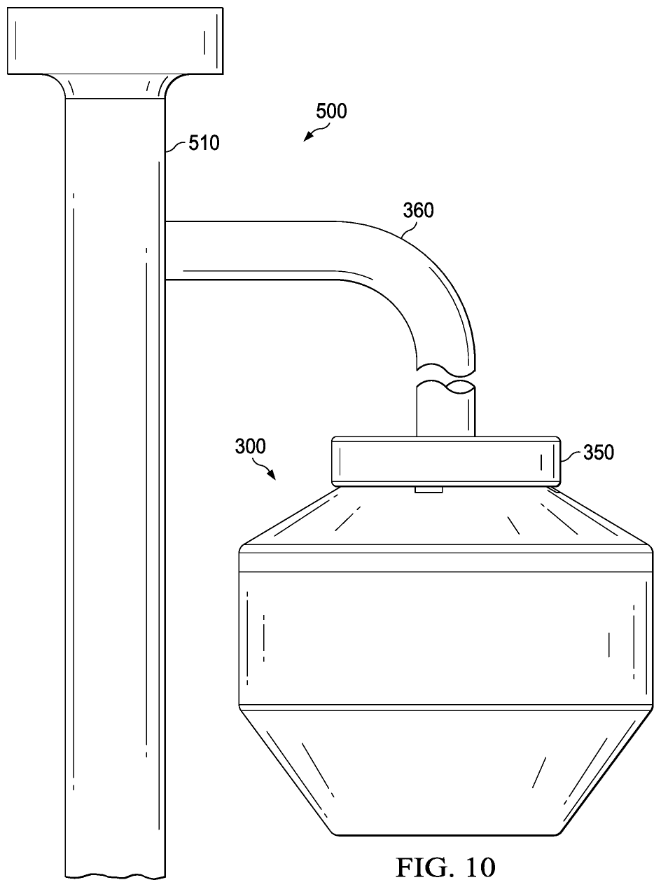

Reference is now made to FIG. 7, which depicts an exploded view of housing 300 for enclosing a wireless access point 100 according to the present disclosure. Housing 300 may comprise a bottom member 310, which may generally have a bowl-like shape, a top member 320 configured to be coupled to the bottom member 310, and a lid 350 for closing the top of housing 300. Top member 320 may comprise an external threaded ridge 330 configured to matably couple with a corresponding internal threaded portion (not shown) in bottom member 310. Once wireless access point 100 is positioned and secured within housing 300, top member 320 may be secured to bottom member 310. The top member 320 may couple to bottom member 310 such that housing 300 may close in a manner similar to the closing of a lid to a jar. Top member 320 may further comprise an external threaded neck 340 for matably engaging internal threading (not shown) of lid 350. The top surface of lid 350 may further be coupled to conduit 360, a hollow pipe-like connector for connecting to support column 510 (shown in FIG. 10).

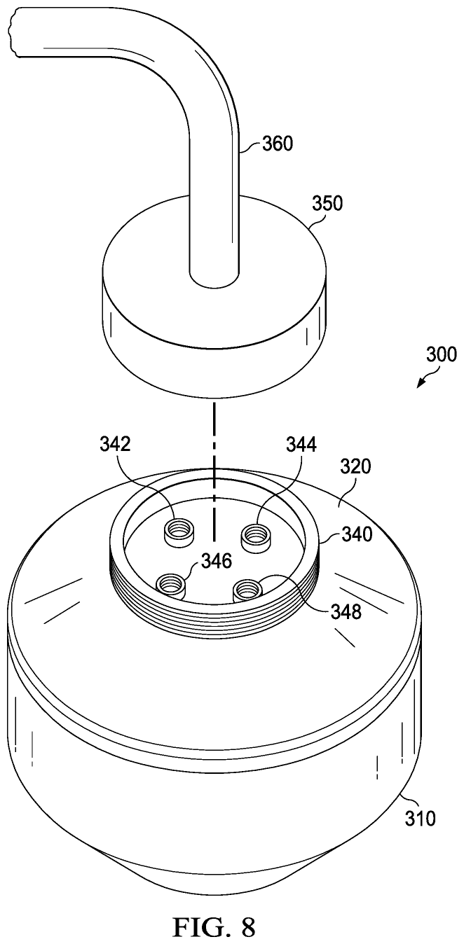

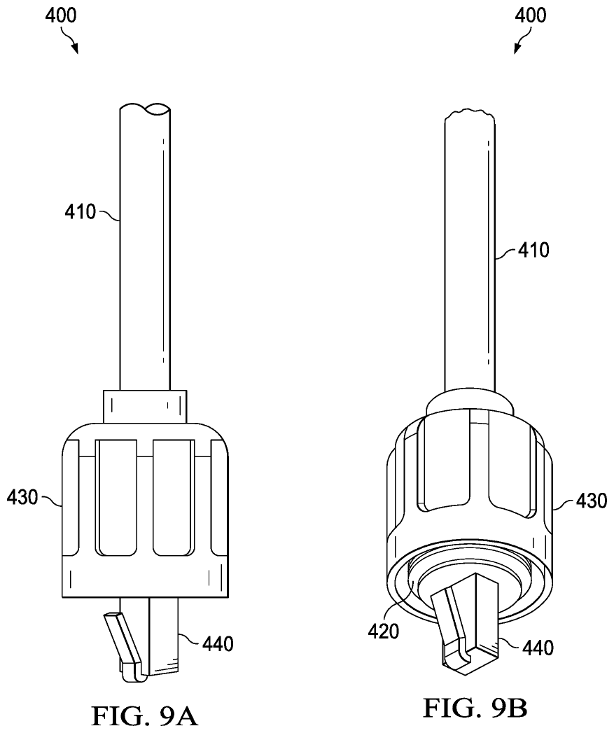

Reference is now made to FIG. 8, which depicts a perspective view of partially assembled housing 300, and to FIGS. 9A and 9B, which depict plan and perspective views, respectively, of a cable mount system 400. As shown in FIG. 8, the inside portion of the neck 340 of the top member 320 of housing 300 may comprise one or more cable holes 342, 344, 346, 348. Each cable hole 342, 344, 346, 348 may be configured to receive one cable mount system 400 (shown in FIGS. 9A and 9B). A cable mount system 400 may comprise a cable 410, a mount 420, a cable covering 430, and a coupler 440. Cable 410 may comprise ethernet, fiber, power, or other such cable that may be connected to the electronic circuit board 160 of the wireless access point 100. A cable 410 may mount to a cable hole 342, 344, 346, or 348 on housing 300 via cable mount 420, which may be threaded into a cable hole 342, 344, 346, 348. Coupler 440 of the cable mount system may be inserted through a cable hole 342, 344, 346, 348 and into housing 300, where it may be connected to components of the electronic circuit board 160 (of FIG. 1). Cable covering 430 may be disposed over mount 420 and may serve as an impermeable seal to ensure protection of the interior of the housing (including the wireless access point 100) from liquid, particles, or other matter. As shown in FIG. 8, four cables may be mounted to the four cable holes 342, 344, 346, 348 via mounts. Although four cable holes are shown in FIG. 8, the present disclosure is not limited to any particular number of cable holes or corresponding cable mount systems. The mounted cables may be gathered into a single bundle and fed through conduit 360 for connection to a power/control system within support column 510 (FIG. 10).

Reference is now made to FIG. 10, which depicts a wireless access point assembly 500 according the present disclosure. Cables mounted to the cable holes 342, 344, 346, 348 (FIG. 8) run through conduit 360 for connection to a power and control center housed within support column 510. Support column 510 may resemble a lamp post or other street fixture that may blend into a cityscape. As such, the wireless access point assembly 500 of the present disclosure may be used in connection with smart cities, stadiums, aviation centers, and other highly populated centers where public Wi-Fi connectivity is desired.

With further reference to the aforedescribed figures, an implementation of a method of configuring a wireless access point according to the present disclosure may comprise: mounting a first set of antennas operating at a first wireless radio band in a first layer around a support structure; and mounting a second set of antennas operating at a second wireless radio band in a second layer around the support structure, wherein the first layer and the second layer form a stacked configuration. The method may further comprise dividing at least one of said first layer and second layer into sectors, wherein if said first layer is divided into sectors, each antenna of said first set of antennas is assigned to a different sector; and wherein if said second layer is divided into sectors, each antenna of said second set of antennas is assigned to a different sector. Incorporating by reference the foregoing paragraphs of the disclosure, the method may further comprise any or all of the steps described above with the respect to the wireless access point 100.

It is to be understood the implementations are not limited to particular systems or processes described which may, of course, vary. It is also to be understood that the terminology used herein is for the purpose of describing particular implementations only, and is not intended to be limiting. As used in this specification, the singular forms “a”, “an” and “the” include plural referents unless the content clearly indicates otherwise.

Although the present disclosure has been described in detail, it should be understood that various changes, substitutions and alterations may be made herein without departing from the spirit and scope of the disclosure as defined by the appended claims. Moreover, the scope of the present application is not intended to be limited to the particular embodiments of the process, machine, manufacture, composition of matter, means, methods and steps described in the specification. As one of ordinary skill in the art will readily appreciate from the disclosure, processes, machines, manufacture, compositions of matter, means, methods, or steps, presently existing or later to be developed that perform substantially the same function or achieve substantially the same result as the corresponding embodiments described herein may be utilized according to the present disclosure. Accordingly, the appended claims are intended to include within their scope such processes, machines, manufacture, compositions of matter, means, methods, or steps.

1. A modular circuit board for use in a telecommunications network comprising:
a plurality of modules, each module operable as an independent circuit board and capable of communicating with a device; and
a central controller for processing information and distributing workload across the plurality of modules.

2. The modular circuit board of claim 1, wherein said each module of the plurality of modules is interchangeable.

3. The modular circuit board of claim 1, wherein said each module of the plurality of modules is removeable.

4. The modular circuit board of claim 1, wherein said each module of the plurality of modules is customizable.

5. The modular circuit board of claim 1, wherein said each module of the plurality of modules comprises:
a central processing unit;
a memory;
a storage; and
a bus structure for coupling with the central controller.

6. The modular circuit board of claim 1, wherein the plurality of modules comprises:
a radio module for providing Wi-Fi radio connectivity.

7. The modular circuit board of claim 6, wherein the radio module may be configured to be electrically coupled to at least one antenna to provide the Wi-Fi radio connectivity.

8. The modular circuit board of claim 1, wherein the plurality of modules comprises:
one or more of a point-to-point module, a point-to-multipoint module, and a multipoint-to-multipoint module for providing long distance connectivity.

9. The modular circuit board of claim 1, wherein the plurality of modules comprises:
a cellular module for providing cellular wide area network (WAN) connectivity.

10. The modular circuit board of claim 1, wherein the plurality of modules comprises:
a virtual private network (VPN) module for providing secure and encrypted connectivity.

11. The modular circuit board of claim 1, wherein the plurality of modules comprises:
a security module for detecting and protecting against system intrusion.

12. The modular circuit board of claim 1, wherein the plurality of modules comprises:
an analytics module for collecting and sending data to a management platform to improve performance.
